(19) United States
(12) Patent Application Publication
(10) Pub. No.: US 2019/0049778 A1
(43) Pub. Date: Feb. 14, 2019

(54) LIQUID CRYSTAL DISPLAY DEVICE

(71) Applicants: HKC Corporation Limited, Shenzhen City, Guangdong (CN); Chongqing HKC Optoelectronics Technology Co., Limited, Chongqing (CN)

(72) Inventor: Yu-Jen CHEN, Chongqing (CN)

(21) Appl. No.: 15/555,297

(22) PCT Filed: Jul. 7, 2017
(86) PCT No.: PCT/CN2017/092164

§ 371 Date: Sep. 1, 2017

(30) Foreign Application Priority Data
Feb. 24, 2017 (CN) 201710103414.0

(51) Int. Cl. G02F 1/1335; H01L 27/12

(52) U.S. Cl. CPC G02F 1/133514; G02F 1/133512; G02F 1/133602; H01L 27/1218

(57) ABSTRACT

This application relates to a liquid crystal display device, comprising: a first substrate having an external surface; a second substrate disposed opposite to the first substrate; a liquid crystal layer disposed between the first substrate and the second substrate; and a light-shielding unit disposed at a periphery of the external surface of the first substrate; wherein a glass member at an edge end of the first substrate has a size larger than a size of a glass member at an edge end of the second substrate.

### FIELD

This application relates to a frameless design method, in particular to a liquid crystal display device.

### RELATED ART

TFT-LCD is the acronym of Thin-Film-Transistor Liquid-Crystal Display. A TFT-LCD is a backlight liquid crystal display, composed of a liquid crystal display panel and a backlight module, wherein the liquid display panel comprises a first substrate of a color filter (CF) substrate, a second substrate of a thin-film transistor (TFT) substrate, and liquid crystals (LCs) sandwiched between the CF substrate and the TFT substrate. The LCD displays images by re-arranging liquid crystal molecules in a liquid crystal layer while a voltage is applied to the electrodes on an array substrate and a filter substrate. As the LCD is not self-luminous, a backlight module is required. A backlight module may include a light source such as a light-emitting diode, and a fluorescent lamp, a light guide, a prism sheet, a diffuser, a protective sheet, and the like.

To provide a strong unitary sense of the displayed pictures, the trend of LCDs moves toward frameless designs. When the frame is eliminated, a problem of lateral light leakage at edges must be overcome, or otherwise there would be a peripheral light leakage. An existing method to solve this problem is to apply a side seal all over the edge end surface of an open cell of a frameless product, so that the light is absorbed and blocked. However, this method requires additional materials and manufacturing processes, thus causing great inconvenience.

### SUMMARY

In order to solve the technical problem above, this application aims to provide a frameless design method, in particular for a liquid crystal display device, to solve the problem of lateral light leakage at the edge of a frameless liquid crystal display, wherein by utilizing the outward convex of a color filter glass and disposing a black photoresist, refracted light on the end surface of the substrate array are effectively extinguished and absorbed. In this way, the only requirement is to set a cutting position of the color filter substrate during cutting of the substrate glass, and no additional materials or manufacturing processes are required.

The objectives of this application and solutions of the technical problems thereof are achieved by the following technical solutions. A liquid crystal display panel according to this application comprises: a first substrate having an external surface; a second substrate disposed opposite to the first substrate; a liquid crystal layer disposed between the first substrate and the second substrate; and a light-shielding unit disposed at a periphery of the external surface of the first substrate, wherein a glass member at an edge end of the first substrate has a size larger than a size of a glass member at an edge end of the second substrate.

The objectives of this application and solutions of the technical problems thereof may also be further be achieved by the following technical measures.

In one embodiment of this application, when the light-shielding unit is disposed at a periphery of the external surface of the first substrate, the light-shielding unit is located between the first substrate and the second substrate, and extends beyond the second substrate.

In one embodiment of this application, the light-shielding unit is a black material.

In one embodiment of this application, the black material is a black photoresist.

In one embodiment of this application, the first substrate is a color filter substrate.

In one embodiment of this application, the second substrate is a thin-film transistor substrate.

In one embodiment of this application, the glass member at the edge end of the first substrate is exposed.

In one embodiment of this application, the size of the glass member at the edge end of the first substrate minus the size of the glass member at the edge of the second substrate is a positive value.

Another objective of this application is to provide a liquid crystal display device comprising a backlight module and a liquid crystal display panel, and the liquid crystal display panel comprises; a first substrate having an external surface; a second substrate disposed opposite to the first substrate; a liquid crystal layer disposed between the first substrate and the second substrate; and a light-shielding unit disposed at a periphery of the external surface of the first substrate, wherein a glass member at an edge end of the first substrate has a size larger than a size of a glass member at an edge end of the second substrate.

The objectives of this application and solutions of the technical problems thereof may also be further achieved by the following technical measures.

In one embodiment of this application, when the light-shielding unit is disposed at the periphery of the external surface of the first substrate, the light-shielding unit is located between the first substrate and the second substrate, and extends beyond the second substrate.

In one embodiment of this application, the light-shielding unit is a black material.

In one embodiment of this application, the black material is a black photoresist.

In one embodiment of this application, the first substrate is a color filter substrate.

In one embodiment of this application, the second substrate is a thin-film transistor substrate.

In one embodiment of this application, the glass member at the edge end of the first substrate is exposed.

In one embodiment of this application, the size of the glass member at the edge end of the first substrate minus the size of the glass member at the edge of the second substrate is a positive value.

Yet another objective of this application is to provide a liquid crystal display device comprising: a backlight module; and a liquid crystal display panel comprising: a thin-film transistor substrate; a color filter substrate disposed opposite to the thin-film transistor substrate, wherein the color filter substrate has an external surface, a glass member at an edge end of the color filter substrate is exposed, the glass member at the edge end of the color filter substrate has a size larger than a size of a glass member at an edge end of the thin-film transistor substrate, and the size of the glass member at the edge end of the color filter substrate minus the size of the glass member at the edge end of the thin-film transistor substrate is a positive value; a liquid crystal layer disposed between the color filter substrate and the thin-film transistor substrate; and a light-shielding unit made from a black photoresist or black ink, wherein the light-shielding unit is formed at a periphery of the external surface of the color filter substrate by an exposure and development process or a printing process, is located between the color filter substrate and the thin-film transistor substrate, and extends from the periphery of the external surface of the color filter substrate to beyond the glass of the thin-film transistor substrate.

This application is directed to solving the problem of lateral light leakage at the edge of a frameless liquid crystal display, wherein by utilizing the outward convex of the color filter glass and disposing a black photoresist to directly replace the conventional mode of applying a side seal all over the edge end surface, the leaked light at the end surface is absorbed, and the manufacturing process is made easier.

### BRIEF DESCRIPTION OF THE DRAWINGS

FIG. 1 is a structural diagram of an exemplary backlight module of a conventional liquid crystal display.

FIG. 2a is a schematic diagram of an exemplary external frame design of a display panel.

FIG. 2b is a schematic diagram of a frameless design of a display panel according to an embodiment of this application.

FIG. 3a is a schematic diagram of an exemplary design having a frame.

FIG. 3b is a schematic diagram of an exemplary frameless side seal design.

FIG. 4 is a schematic diagram of a panel array having a black material disposed on a surface of a color filter glass substrate according to an embodiment of this application.

### DETAILED DESCRIPTION

The following description of various embodiments is made with reference to the drawings for illustrating specific applicable embodiments of the present application. Terms of directions referred in this application, such as “up”, “down”, “front”, “back/rear”, “left”, “right”, “internal/inside/inner”, “external/outside/outer” and “side/lateral”, are only used in reference to the directions in the accompanying figures. Accordingly, the terms of directions used are intended to explain and facilitate understanding of the application and are not intended to limit the application.

The drawings and descriptions are to be considered in nature as illustrative and not restrictive. In the drawings, identical reference numerals refer to similar elements. In addition, for purposes of understanding and ease of description, the size and thickness of each component shown in the drawings are arbitrarily given, and the application is not limited thereto.

In the drawings, the thicknesses of layers, films, panels, areas and the like are exaggerated for clarity. In the drawings, for purposes of understanding and ease of description, the thicknesses of some layers and areas are exaggerated. It should be understood that when an component of a layer, film, area, substrate, or the like is described as being “on/above/over” another component, the component can be directly on the other component, or intervening components may also be present.

Additionally, in the specification, unless explicitly described otherwise, the word “comprise” should be understood as implying the inclusion of the stated components but not the exclusion of any other components. Furthermore, in the specification, “on” means located above or below the target component, without necessarily meaning being located on the top with respect to the direction of gravity.

To further illustrate the technological means and effects of the present application taken to achieve a predetermined purpose of the invention, the specific implementation, structures, features and effects of a liquid crystal display device according to the present application are described, in conjunction with the drawings and preferred embodiments, in details as follows.

A liquid crystal display (LCD) applies an electrical field to liquid crystals between two glass substrates to display numerals or images. The liquid crystals are composed of substances between liquid and solid states. Since the LCD is not self-luminous, a backlight module is required to provide light. Pictures are formed by controlling light transmission of the liquid crystal display panel. The liquid crystals are uniformly arranged in the liquid crystal display panel.

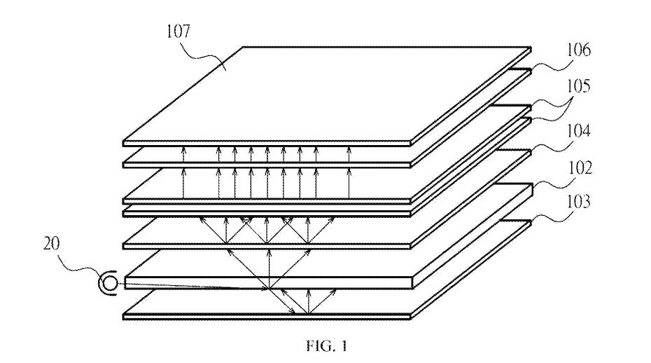

In a conventional LCD, the backlight module (as shown in FIG. 1) includes a light source 20, a light guide 102, a reflector 103, a diffuser 104, a prism sheet 105 and a protective sheet 106. Firstly, the light source 20 is used to emit light into the LCD. There are currently a variety of different light sources applicable to LCDs. The light guide 102 is positioned below a liquid crystal display panel 107 and is proximate to the side of the light source 20. The light guide 102 is used to convert a spot light beam produced by the light source 20 into a planar light beam, and project the planar light beam onto the liquid crystal display panel 107.

The reflector 103 is disposed below the light guide 102. The reflector 103 is used to reflect the light emitted by the light source 21) to the liquid crystal display panel 107 in front of the reflector 103. The diffuser 104 is disposed above the light guide 102 to homogenize the light passing through the light guide 102. The light is diffused in both horizontal and vertical directions when passing through the diffuser 104. At this point, the light brightness will be reduced rapidly. In this regard, the prism sheet 105 is used to refract and collect light to enhance brightness. Generally, two prism sheets 105 are aligned in a perpendicular manner.

The protective sheet 106 is disposed above the prism sheets 105. When the two prism sheets 105 aligned perpendicularly are used, the protective sheet 106 can protect the prism sheets 105 from scratching, and occurrences of the Moire effect. A backlight module of a conventional LCD comprises the components above.

In general, when the prism sheets 105 are installed normally, directions of a plurality of cell prisms will be arranged regularly on a transparent material film. The prism sheets 105 are used to refract a light ray passing through the light guide 102 and diffused by the diffuser 104. In general, if the width for light transmission and refraction is smaller, the light in the transmission and refraction areas will appear brighter. Conversely, if the width for light transmission and refraction is larger, the light in the transmission and refraction areas will appear darker.

In recent years, LCDs have been in the development toward large-sized panels. Therefore, one consideration is how to maintain the density of light emitted by the backlight module to be above a predetermined level; moreover, when the trend of LCDs moves toward frameless designs to provide a strong unitary sense of the displayed pictures, the frame is eliminated, so that a problem of lateral light leakage at edges must be overcome, or otherwise there would be a peripheral light leakage. In addition, when a product having no frame on four sides displays with the panel array side up, the peripheral metal will reflect light and cause poor visual perception to impact the quality of the panel. As a result, how to homogenize the light for viewing while solving the problem of lateral light leakage at the edges will be an important reference factor of a large-sized panel.

The liquid crystal display device of this application may include a backlight module and a liquid crystal display panel. The crystal display panel may include a thin-film transistor substrate, a color filter substrate, and a liquid crystal layer formed therebetween.

In one embodiment, the liquid crystal display panel of this application may be a curved display panel, and the liquid crystal display device of this application may be a curved display device.

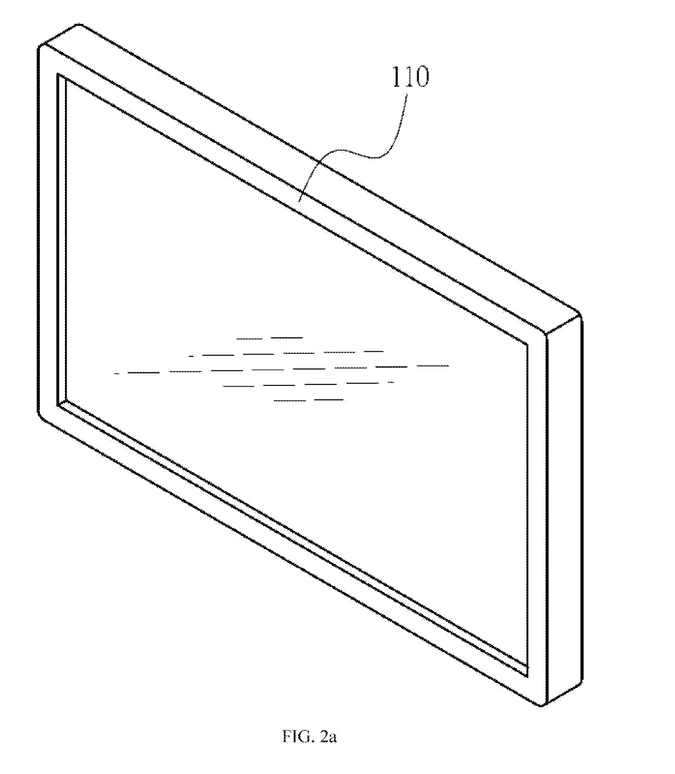

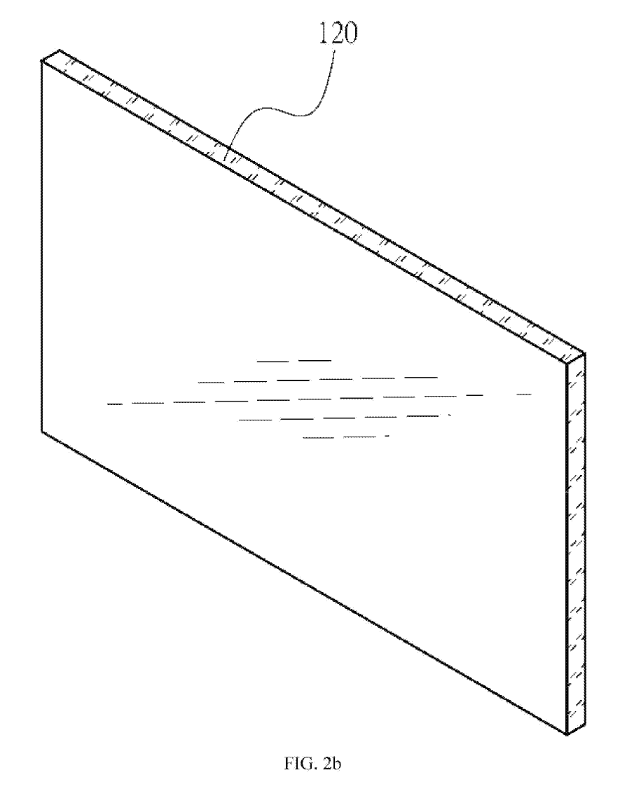

FIG. 2a is a schematic diagram of an exemplary external frame design of a display panel, and FIG. 2b is a schematic diagram of a frameless design of a display panel according to an embodiment of this application. Referring to FIG. 2a and FIG. 2b, TFT-LCDs moves toward frameless designs to provide a strong unitary sense of the displayed pictures, and to eliminate the frame 110, a problem of lateral light leakage at edges must be overcome, or otherwise there would be a peripheral light leakage. An existing method to solve this problem is to apply a layer of side seal 120 to the edge end surface of the open cell of a frameless product, so that the light is absorbed and blocked. However, this method requires additional materials and manufacturing processes, and thus is quite inconvenient.

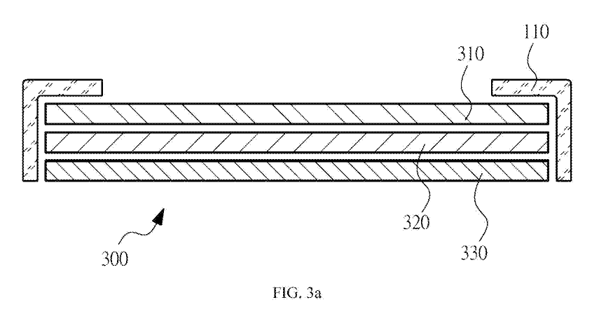

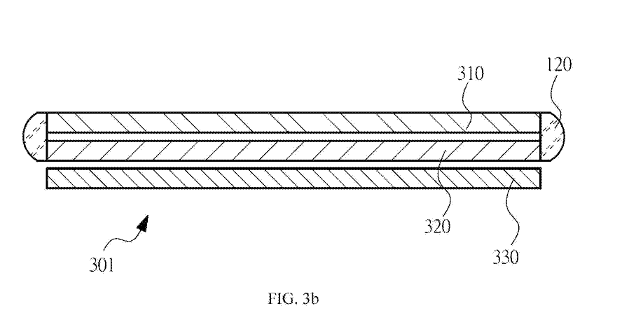

FIG. 3a is a schematic diagram of an exemplary design having a frame. Referring to FIG. 3a, in one embodiment, a liquid crystal display device 300 comprises a liquid crystal display panel, including: a first substrate 310 having an external surface; a second substrate 320 disposed opposite to the first substrate 310; a backlight module 330; and a frame 110 disposed at a periphery of the external surface of the liquid crystal display panel to absorb and block light, but this method requires additional materials and manufacturing processes, thus causing great inconvenience.

FIG. 3b is a schematic diagram of an exemplary frameless side seal design. Referring to FIG. 3b, in a conventional frameless product, a liquid crystal display device 301 comprises: a first substrate 310 having an external surface; a second substrate 320 disposed opposite to the first substrate 310; a backlight module 330; and a layer of side seal 120 applied to the edge end surface of an open cell, so that light is absorbed and blocked. However, this method requires additional materials and manufacturing processes, introducing higher manufacturing costs and thus rendering said method unsuitable for industrial production.

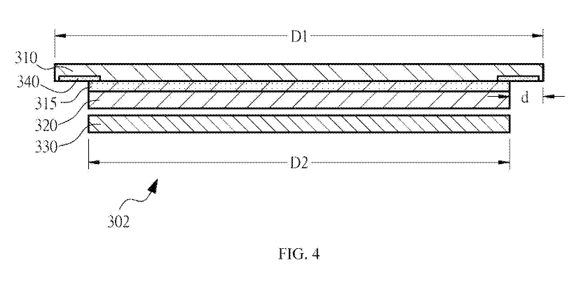

FIG. 4 is a schematic diagram of a panel array having a black material on a surface of a color filter substrate according to an embodiment of this application. Referring to FIG. 4, in an embodiment of this application, a liquid crystal display panel comprises: a first substrate 310 having an external surface; a second substrate 320 disposed opposite to the first substrate 310; and a light-shielding unit 340 disposed at a periphery of the external surface of the first substrate 310, wherein the size D1 of a glass member at an edge end of the first substrate 310 is larger than the size D2 of a glass member at an edge end of the second substrate 320. In this application, refracted light on the end surface of a thin-film transistor substrate 320 are effectively extinguished and absorbed by utilizing the outward convex glass of a color filter substrate 310 and disposing a black photoresist 340. In this way, the only requirement is to set a cutting position of the color filter substrate 310 during glass cutting of the color filter substrate 310, and no additional materials or manufacturing processes are required.

In one embodiment, the liquid crystal display panel can be a thin film transistor liquid crystal display panel, a curved panel, or any other backlight liquid crystal display panel.

In one embodiment, when the light-shielding unit 340 is disposed at the periphery of the external surface of the first substrate 310, the light-shielding unit 340 is located between the first substrate 310 and the second substrate 320, and extends beyond the second substrate 320.

In one embodiment, the light-shielding unit 340 is a black material.

In one embodiment, the black material is a black photoresist.

In one embodiment, the first substrate 310 is a color filter substrate.

In one embodiment, the second substrate 320 is a thin-film transistor substrate.

In one embodiment, the liquid crystal display panel further comprises a liquid crystal layer 315 disposed between the first substrate 310 and the second substrate 320.

In one embodiment, the glass member at the edge end of the first substrate 310 is exposed.

In one embodiment, the size D1 of the glass member at the edge end of the first substrate 310 minus the size D2 of the glass member at the edge of the second substrate 320 is d (d>0).

In one embodiment, the mode of forming the light-shielding unit 340 comprises an exposure and development process or a printing process.

In one embodiment, the mode of forming the first substrate 310 and the second substrate 320 comprises forming by photoresist coating, exposing, developing and photon asking, processes.

In one embodiment, the light-shielding unit 340 is a black material, and the light-shielding unit 340 can be made from an insulating black ink and is located within a frame area, so that a black frame is shown on a protective cover, thus creating a look-and-feel of a frame in a frameless design to enhance the aesthetic quality of the appearance.

Still referring to FIG. 4, in one embodiment of this application, a liquid crystal display device 302 comprises: a backlight module 330; and a liquid crystal display panel comprising: a first substrate 310 having an external surface; a second substrate 320 disposed opposite to the first substrate 310; and a light-shielding unit 340 disposed at a periphery of the external surface of the first substrate 310, wherein the size D1 of a glass member at an edge end of the first substrate 310 is larger than the size D2 of a glass member at an edge end of the second substrate 320. In this application, refracted light on the end surface of a thin-film transistor substrate 320 are effectively extinguished and absorbed by utilizing the outward convex glass of a color filter substrate 310 and disposing a black photoresist 340. In this way, the only requirement is to set a cutting position of the color filter substrate 310 during glass cutting of the color filter substrate 310, and no additional materials or manufacturing processes are required.

In one embodiment, the liquid crystal display panel can be a thin-film transistor liquid crystal display panel, a curved panel, or any other backlight liquid crystal display panel.

In one embodiment, when the light-shielding unit 340 is disposed at the periphery of the external surface of the first substrate 310, the light-shielding unit 340 is located between the first substrate 310 and the second substrate 320, and extends beyond the second substrate 320.

In one embodiment, the light-shielding unit 340 is a black material.

In one embodiment, the black material is a black photoresist.

In one embodiment, the first substrate 310 is a color filter substrate.

In one embodiment, the second substrate 320 is a thin-film transistor substrate.

In one embodiment, the liquid crystal display panel further comprises a liquid crystal layer 315 disposed between the first substrate 310 and the second substrate 320.

In one embodiment, the glass member at the edge end of the first substrate 310 is exposed.

In one embodiment, the size D1 of the glass member at the edge end of the first substrate 310 minus the size D2 of the glass member at the edge of the second substrate 320 is d (d>0).

In one embodiment, the mode of forming the light-shielding unit 340 comprises an exposure and development process or a printing process.

In one embodiment, the mode of forming the first substrate 310 and the second substrate 320 comprises forming by photoresist coating, exposing, developing and photomasking, processes.

In one embodiment, the light-shielding unit 340 is a black material, and the light-shielding unit 340 can be made from an insulating black ink and is located within a frame area, so that a black frame is shown on a protective cover, thus creating a look-and-feel of a frame in a frameless design to enhance the aesthetic quality of the appearance.

Still referring to FIG. 4, specifically, in one embodiment, in a thin film transistor liquid crystal display, a glass member at an edge end is exposed, and the size D1 of the glass member at the edge end of the first substrate (color filter substrate) 310 minus the size D2 of the glass member at the edge of the second substrate (thin-film transistor substrate) 320 is d (d>0).

In one embodiment, in a thin-film transistor liquid crystal display, the glass member at the edge end is exposed, and the size D1 of the glass member at the edge end of the first substrate (color filter substrate) 310 minus the size D2 of the glass member at the edge of the second substrate (thin-film transistor substrate) 320 is d (d>0), and the periphery of the external surface of the first substrate (color filter substrate) 310 has a black photoresist 340.

In one embodiment, in a thin-film transistor liquid crystal display, the glass member at the edge end is exposed, and the size D1 of the glass member at the edge end of the first substrate (color filter substrate) 310 minus the size D2 of the glass member at the edge of the second substrate (thin-film transistor substrate) 320 is d (d>0), the periphery of the external surface of the first substrate (color filter substrate) 310 has a black photoresist 340, and the black photoresist 340 extends beyond the glass of the thin-film transistor substrate 320.

In one embodiment of this application, the backlight module 330 further comprises: a light guide; and a light source disposed on a lateral surface or a rear surface of the light guide. The light source is, for example, a light-emitting diode or a fluorescent lamp.

In one embodiment, a liquid crystal display panel comprises: a color filter substrate 310 having an external surface; a thin-film transistor substrate 320 disposed opposite to the color filter substrate 310; a liquid crystal layer 315 disposed between the color filter substrate 310 and the thin-film transistor substrate 320; and a light-shielding unit 340 disposed at a periphery of the external surface of the color filter substrate 310, wherein a glass member at an edge end of the color filter substrate 310 is exposed, the glass member at the edge end of the color filter substrate 310 has a size larger than a size of a glass member at an edge end of the thin-film transistor substrate 320, and the size of the glass member at the edge end of the color filter substrate 310 minus the size of the glass member at the edge end of the thin-film transistor substrate 320 is a positive value. The light-shielding unit 340 is made from a black photoresist or black ink, the light-shielding unit 340 is formed at a periphery of the external surface of the color filter substrate 310 by an exposure and development process or a printing process, and is located between the color filter substrate 310 and the thin-film transistor substrate 320, and the light-shielding unit 340 extends from the periphery of the external surface of the color filter substrate 310 to beyond the glass of the thin-film transistor substrate 320.

This application is directed to solving the problem of lateral light leakage at the edge of a frameless liquid crystal display, wherein by utilizing the outward convex of the color filter glass and disposing a black photoresist to directly replace the conventional mode of applying a side seal all over an edge end surface, the leaked light at the end surface is absorbed, and the manufacturing process is made easier.

Terms such as “in some embodiments” and “in various embodiments” are used repeatedly. These terms generally do not refer to identical embodiments; but they can also refer to identical embodiments. Terms such as “include”, “have” and “comprise” are synonyms, unless the context indicates otherwise.

Those described above are only the preferred embodiments of the present application, and are not intended to limit the present application in any form. Although the application has been disclosed as above in the preferred embodiments, it is not limited thereto. Those skilled in the art, without departing from the scope of the technical solutions of the application, could utilize equivalent embodiments changed or modified to equivalent variations with the disclosed technical content. However, any simple changes, equivalent variations and modifications made to above embodiments based on the spirit of the application, without departing from the content of the technical solutions of the application, still fall within the scope of the technical solutions of the application.

What is claimed is:

1. A liquid crystal display panel, comprising:
a first substrate having an external surface;
a second substrate disposed opposite to the first substrate;
a liquid crystal layer disposed between the first substrate and the second substrate; and
a light-shielding unit disposed at a periphery of the external surface of the first substrate, wherein a glass member at an edge end of the first substrate has a size larger than a size of a glass member at an edge end of the second substrate.

2. The liquid crystal display panel of claim 1, wherein when the light-shielding unit is disposed at the periphery of the external surface of the first substrate, the light-shielding unit is located between the first substrate and the second substrate, and extends beyond the second substrate.

3. The liquid crystal display panel of claim 1, wherein the light-shielding unit is a black material.

4. The liquid crystal display panel of claim 3, wherein the black material is a black photoresist.

5. The liquid crystal display panel of claim 1, wherein the first substrate is a color filter substrate.

6. The liquid crystal display panel of claim 1, wherein the second substrate is a thin-film transistor substrate.

7. The liquid crystal display panel of claim 1, wherein the glass member at the edge end of the first substrate is exposed.

8. The liquid crystal display panel of claim 1, wherein the size of the glass member at the edge end of the first substrate minus the size of the glass member at the edge of the second substrate is a positive value.

9. A liquid crystal display device, comprising:
a backlight module; and
a liquid crystal display panel comprising:
a first substrate having an external surface;
a second substrate disposed opposite to the first substrate;
a liquid crystal layer disposed between the first substrate and the second substrate; and
a light-shielding unit disposed at a periphery of the external surface of the first substrate, wherein a glass member at an edge end of the first substrate has a size larger than a size of a glass member at an edge end of the second substrate.

10. The liquid crystal display device of claim 9, wherein when the light-shielding unit is disposed at the periphery of the external surface of the first substrate, the light-shielding unit is located between the first substrate and the second substrate, and extends beyond the second substrate.

11. The liquid crystal display device of claim 9, wherein the light-shielding unit is a black material.

12. The liquid crystal display device of claim 11, wherein the black material is a black photoresist.

13. The liquid crystal display device of claim 9, wherein the first substrate is a color filter substrate.

14. The liquid crystal display device of claim 9, wherein the second substrate is a thin-film transistor substrate.

15. The liquid crystal display device of claim 9, wherein the glass member at the edge end of the first substrate is exposed.

16. The liquid crystal display device of claim 9, wherein the size of the glass member at the edge end of the first substrate minus the size of the glass member at the edge of the second substrate is a positive value.

17. A liquid crystal display device, comprising:
a backlight module; and
a liquid crystal display panel comprising:
a thin-film transistor substrate;
a color filter substrate disposed opposite to the thin-film transistor substrate, wherein the color filter substrate has an external surface, a glass member at an edge end of the color filter substrate is exposed, the glass member at the edge end of the color filter substrate has a size larger than a size of a glass member at an edge end of the thin-film transistor substrate, and the size of the glass member at the edge end of the color filter substrate minus the size of the glass member at the edge end of the thin-film transistor substrate is a positive value;
a liquid crystal layer disposed between the color filter substrate and the thin-film transistor substrate; and
a light-shielding unit made from a black photoresist or black ink, wherein the light-shielding unit is formed at a periphery of the external surface of the color filter substrate by an exposure and development process or a printing process, is located between the color filter substrate and the thin-film transistor substrate, and extends from the periphery of the external surface of the color filter substrate to beyond the glass member of the thin-film transistor substrate.
